(19) United States
(12) Patent Application Publication
(10) Pub. No.: US 2015/0340562 A1
(43) Pub. Date: Nov. 26, 2015

(54) LIGHT EMITTING DEVICE AND METHOD OF FABRICATING THE SAME

(71) Applicant: Seoul Viosys Co., Ltd., Ansan-si (KR)

(72) Inventors: Min Kyu Kim, Ansan-si (KR); Jung Whan Jung, Ansan-si (KR); Kyung Hae Kim, Ansan-si (KR); Woo Chul Kwak, Ansan-si (KR)

(21) Appl. No.: 14/715,286

(22) Filed: May 18, 2015

(30) Foreign Application Priority Data
May 20, 2014 (KR) 10-2014-0060231
Sep. 26, 2014 (KR) 10-2014-0129305
Dec. 30, 2014 (KR) 10-2014-0193540

(51) Int. Cl. H01L 33/32; H01L 33/00; H01L 33/38; H01L 33/06

(52) U.S. Cl. CPC H01L 33/325; H01L 33/06; H01L 33/0025; H01L 33/0075; H01L 33/38

(57) ABSTRACT

Embodiments provide a method of growing a p-type nitride semiconductor, and a light emitting device fabricated using the same. The method of growing a p-type nitride semiconductor includes growing a p-type nitride semiconductor layer on a growth substrate by introducing a group III element source, a group V element source, and a p-type dopant into a chamber at a first temperature; and cooling the interior of the chamber from the first temperature to a second temperature, wherein the p-type dopant is introduced into the chamber for at least some part of the cooling of the interior of the chamber from the first temperature to the second temperature. According to the present disclosed technology, it is possible to prevent diffusion of the p-type dopant from a p-type nitride semiconductor layer into the chamber.

### PRIORITY CLAIMS AND CROSS-REFERENCE TO RELATED APPLICATION

This patent document claims priorities and benefits of Korean Patent Application No. 10-2014-0060231, filed on May 20, 2014, Korean Patent Application No. 10-2014-0129305, filed on Sep. 26, 2014 and Korean Patent Application No. 10-2014-0193540, filed on Dec. 30, 2014, the contents of which are incorporated by reference.

### TECHNICAL FIELD

This patent document relates to a light emitting device and a method of fabricating the same. In exemplary embodiments, a method of growing a p-type nitride semiconductor having low surface contact resistance is provided, and a light emitting device which is fabricated using the same method is provided.

### BACKGROUND

Nitride semiconductors such as GaN have excellent electromagnetic properties and are widely used for light emitting devices such as light emitting diodes. A nitride semiconductor device using a P-N junction, such as a light emitting diode, includes a p-type semiconductor layer and an n-type semiconductor layer. Here, each of the p-type semiconductor layer and the n-type semiconductor layer is doped with conductivity type determining impurities, such as Mg and Si.

Generally, a light emitting device using a nitride semiconductor is formed by growing an n-type nitride semiconductor layer, an active layer, and a p-type nitride semiconductor layer on a growth substrate. In the process of growing the light emitting diode, the p-type nitride semiconductor layer is grown by introducing a group III element, a group V element, and an impurity precursor such as Mg into a growth chamber. Here, Mg substitutes for a site of the group III element such that a nitride semiconductor is doped into a p-type. Such a p-type nitride semiconductor layer is generally grown in a growth chamber under a hydrogen atmosphere.

### SUMMARY

Exemplary embodiments provide a method of fabricating a light emitting device, which can prevent increase in contact resistance of a p-type nitride semiconductor layer in the process of lowering the internal temperature of a nitride semiconductor growth chamber.

Exemplary embodiments provide a light emitting device which includes a p-type nitride semiconductor layer having low contact resistance and thus a low forward voltage and high luminous efficiency.

In accordance with one exemplary embodiment, a method of fabricating a light emitting device is provided to include: growing an n-type nitride semiconductor layer over a growth substrate; growing an active layer over the n-type nitride semiconductor layer; growing a p-type nitride semiconductor layer on the active layer by introducing a group III element source, a group V element source, and a p-type dopant into a chamber at a first temperature; and cooling an interior of the chamber from the first temperature to a second temperature, wherein the p-type dopant is introduced into the chamber for at least some part of the cooling process of the interior of the chamber from the first temperature to the second temperature.

Accordingly, since Mg out-diffusion can be prevented, it is possible to provide a light emitting device including a p-type nitride semiconductor layer having low contact resistance.

In some implementations, the cooling of the interior of the chamber from the first temperature to the second temperature can include growing a diffusion barrier layer containing the p-type dopant over the p-type nitride semiconductor layer.

In some implementations, the p-type dopant can include Mg and the diffusion barrier layer can include at least one of Mg and MgₓN_{y}.

In some implementations, during cooling of the interior of the chamber from the first temperature to the second temperature, the introducing of the group III element source into the chamber can be stopped, and the introduction of the group V element source can be maintained.

In some implementations, the method of fabricating a light emitting device can further include, after cooling the interior of the chamber to the second temperature, maintaining the interior of the chamber at the second temperature for a predetermined period of time, wherein the p-type dopant can be introduced into the chamber for at least some part of a period of the maintaining, wherein growing the diffusion barrier layer is continued during the maintaining of the interior of the chamber at the second temperature.

Further, during the cooling process and the maintaining process, the introducing of the group V element source is maintained, and a flow rate of the group V element source introduced during the growth of the p-type nitride semiconductor layer can be higher than or equal to a flow rate of the group V element source introduced during the growth of the diffusion barrier layer.

In some implementations, a flow rate of the p-type dopant introduced during the growth of the p-type nitride semiconductor layer can be higher than or equal to a flow rate of the p-type dopant introduced during the growth of the diffusion barrier layer.

In some implementations, during the growing of the diffusion barrier layer, the p-type dopant can be introduced into the chamber in a multi-pulse mode, and the diffusion barrier layer can include a structure in which an Mg-rich MgₓN_{y} layer and an Mg-poor MgₓN_{y} layer are repeatedly stacked.

In some implementations, during the growing of the diffusion barrier layer, the group III element source and the p-type dopant can be introduced into the chamber in a multi-pulse mode, and the diffusion barrier layer can include a structure in which an MgₓN_{y} layer and a GaN layer are stacked more than once.

In some implementations, the method can further include, during the cooling of the interior of the chamber from the first temperature to the second temperature, gradually decreasing a flow rate of the group III element source for at least some part of a period of time for which the p-type dopant is introduced into the chamber.

In some implementations, during the maintaining of the interior of the chamber at the second temperature, the group III element source is introduced into the chamber in a multi-pulse mode for at least some part of a period of time for which the p-type dopant is introduced into the chamber, and, in the multi-pulse mode, a subsequent pulse can have a shorter duration than a preceding pulse.

In some implementations, during the growing of the p-type nitride semiconductor layer, increasing a flow rate of the p-type dopant such that the p-type nitride semiconductor layer includes a P-nitride semiconductor layer and a P+-nitride semiconductor layer.

In another aspect, a light emitting device is provided to include: an n-type nitride semiconductor layer; an active layer disposed on the n-type nitride semiconductor layer; a p-type nitride semiconductor layer disposed on the active layer; and a diffusion barrier layer disposed on the p-type nitride semiconductor layer.

Accordingly, it is possible to provide a light emitting device including a p-type nitride semiconductor layer having low contact resistance.

In some implementations, the diffusion barrier layer can include a p-type dopant.

In some implementations, the p-type dopant can include Mg and the diffusion barrier layer can include at least one of Mg or MgₓN_{y}.

In some implementations, the diffusion barrier layer can include a structure in which an Mg-rich MgₓN_{y} layer and an Mg-poor MgₓN_{y} layer are repeatedly stacked.

In some implementations, the diffusion barrier layer can include a structure in which an MgₓN_{y} and a GaN layer are repeatedly stacked.

In some implementations, the diffusion barrier layer has a thickness from 0.3 nm to 5 nm.

In some implementations, the GaN layer can include Mg.

In some implementations, the light emitting device can further include a p-type electrode disposed on the diffusion barrier layer, wherein the p-type electrode can be in ohmic contact with the diffusion barrier layer.

According to embodiments of the disclosed technology, it is possible to prevent out-diffusion of a p-type dopant from a p-type nitride semiconductor layer, thereby avoiding increase in contact resistance of the p-type nitride semiconductor layer.

Further, since the method of growing a p-type nitride semiconductor layer according to the disclosed technology and the light emitting device fabricated using the same can be provided, the light emitting device according to the disclosed technology includes a p-type nitride having low contact resistance and thus can have low forward voltage and high luminous efficiency.

### BRIEF DESCRIPTION OF DRAWINGS

FIG. 1 is a schematic view illustrating out-diffusion of Mg in the typical process of growing a p-type nitride semiconductor layer.

FIG. 2 and FIG. 3 are sectional views illustrating an exemplary method of fabricating a light emitting device according to some embodiments of the present disclosure.

FIG. 4 is a schematic view illustrating an exemplary diffusion barrier layer according to one embodiment of the present disclosure.

FIG. 5 illustrates an exemplary method of growing a p-type nitride semiconductor layer and a diffusion barrier layer according to one embodiment of the present disclosure.

FIG. 6 to FIG. 11 illustrate exemplary methods of growing a p-type nitride semiconductor layer and a diffusion barrier layer according to other embodiments of the present disclosure.

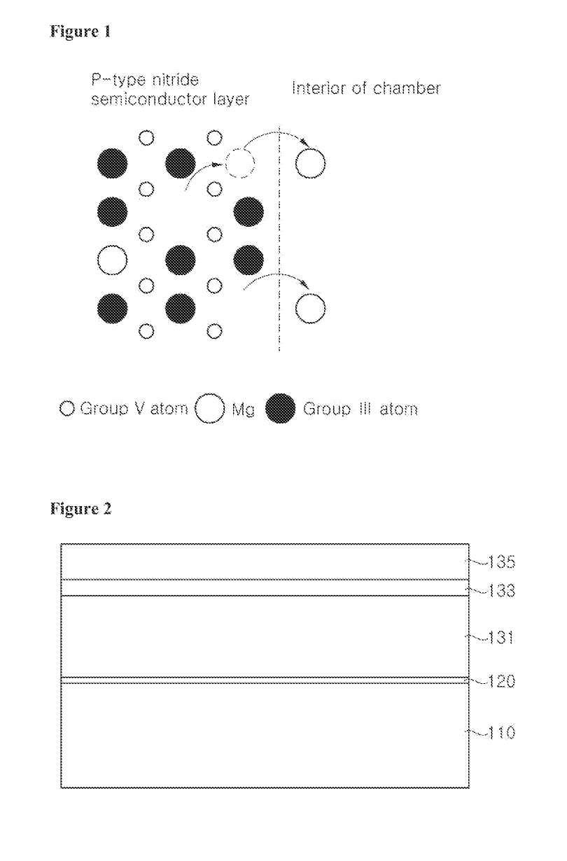

### DETAILED DESCRIPTION

Hereinafter, exemplary implementations of the disclosed technology will be described in detail with reference to the accompanying drawings. It should be understood that the following implementations are provided to facilitate understanding of examples of the disclosed technology. Thus, it should be understood that the disclosed technology is not limited to the following implementations and can be provided in different ways. In addition, it should be noted that the drawings are not to precise scale and some of the dimensions, such as width, length, thickness, and the like, can be exaggerated for convenience of description. It will be understood that when an element such as a layer, film, region or substrate is referred to as being formed, placed or disposed “above” or “on” another element, it can be directly formed, placed or disposed on the other element or intervening elements can also be present. Like components will be denoted by like reference numerals throughout the specification.

When the p-type nitride semiconductor layer is doped with Mg in the growth chamber having a hydrogen atmosphere, dangling bonds of Mg are combined with hydrogen elements, which disrupts functions of Mg as p-type impurities in the nitride semiconductor layer. As a result, doping concentration of Mg does not reach a desired level. To overcome this problem, a published US application No. US 2007/0074651 describes a method of discharging hydrogen gas out of the growth chamber, and annealing the p-type nitride semiconductor layer.

In addition, a surface of the p-type nitride semiconductor layer is brought into ohmic contact with a p-type electrode, and the surface of the p-type nitride semiconductor layer is over-doped with p-type impurities (for example, in a doping concentration 10 times that of an inside of the p-type nitride semiconductor). After completion of growth of the semiconductor layers, during cooling the interior of the chamber or annealing the p-type nitride semiconductor layer, Mg diffuses due to a difference in Mg concentration between the interior of the chamber and the p-type nitride semiconductor layer. In other words, diffusion of Mg from the p-type nitride semiconductor layer into the interior of the chamber occurs, which leads to increase in contact resistance between the p-type nitride semiconductor layer and the p-type electrode.

When contact resistance between the p-type nitride semiconductor layer and the p-type electrode increases, forward voltage of the prepared light emitting device increases. Further, increase of the contact resistance can also lead to deterioration in luminous efficiency. Therefore, there is a need for a manufacturing method or novel structure which can prevent possible increase in contact resistance of a p-type nitride semiconductor layer in the manufacturing process.

In embodiments of the present disclosure, nitride semiconductor layers can be grown in a growth chamber. In some implementations, nitride semiconductor layers can be formed in a metal organic chemical vapor deposition (MOCVD) chamber. Thus, growth conditions as described below can be applied to a case in which nitride semiconductor layers are grown using MOCVD. However, it should be understood that the present disclosure is not limited thereto, and can thus also include a case in which nitride semiconductors are grown using molecular beam epitaxy (MBE), hydride vapor phase epitaxy (HVPE), or the like.

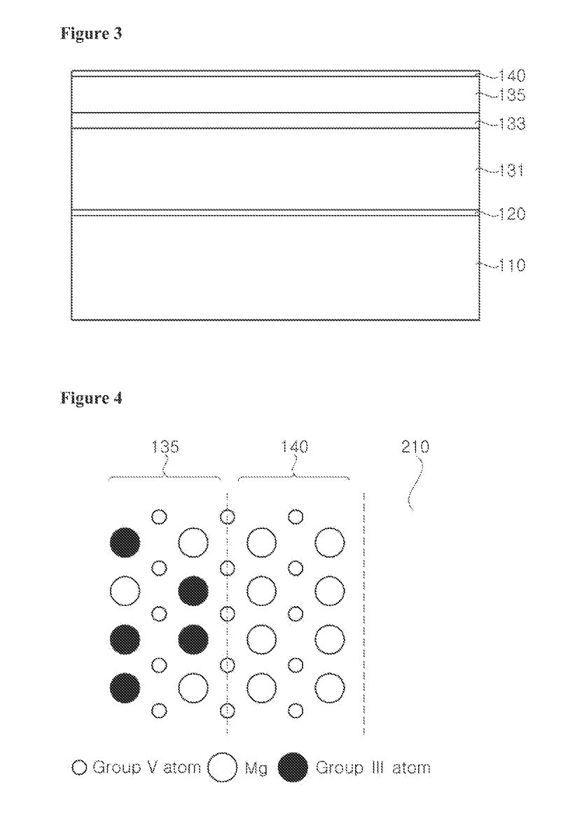

FIG. 2 and FIG. 3 are sectional views illustrating an exemplary method of fabricating a light emitting device according to some embodiments of the present disclosure.

Referring to FIG. 2, an n-type nitride semiconductor layer 131, an active layer 133, and a p-type nitride semiconductor layer 135 are grown on a growth substrate 110. Further, in some implementations, a buffer layer 120 can be formed on the growth substrate 110 before growing the n-type nitride semiconductor layer 131

The growth substrate 110 is not restricted so long as nitride semiconductor layers can be grown on the substrate, and can include an insulating substrate or a conductive substrate. The growth substrate 110 can be or include, for example, a sapphire substrate, a patterned sapphire substrate (PSS), a silicon substrate, a silicon carbide substrate, an aluminum nitride substrate, or a gallium nitride substrate.

The growth substrate 110 is loaded into the growth chamber, and the interior of the chamber can be heated to a predetermined temperature. Internal temperature of the chamber can be variously adjusted according to growth conditions of the nitride semiconductor layers, which will be described in detail below.

The buffer layer 120 can be grown on the growth substrate 110 at a relatively low temperature. For example, the buffer layer 120 can be grown at a temperature of about 500° C. to about 600° C. The buffer layer 120 can serve as a nuclear layer allowing semiconductor layers to be grown into a single crystal in subsequent processes. In addition, the buffer layer can serve to relieve stress and strain caused by lattice mismatch between semiconductor layers grown in subsequent processes and the growth substrate 110.

The buffer layer 120 can include a nitride semiconductor, for example, at least one of AlGaN, AlN, or GaN.

The n-type nitride semiconductor layer 131 can be grown on the growth substrate 110. The n-type nitride semiconductor layer 131 can include a nitride semiconductor such as (Al, Ga, In)N and an n-type dopant. The n-type nitride semiconductor 131 can include a layer which is grown by introducing a group III element source, a group V element source, and an n-type dopant precursor into the chamber at about 900° C. to about 1100° C. Here, the n-type dopant can be or include Si.

In addition, the n-type nitride semiconductor layer 131 can include a monolayer or a multilayer, or can include a supper lattice layer.

The active layer 133 can be grown on the n-type nitride semiconductor layer 131, and can include a nitride semiconductor such as (Al, Ga, In)N. In addition, the active layer can have a multi-quantum well (MQW) structure including a plurality of barrier layers and a plurality of well layers. Here, elements forming semiconductor layers constituting the multi-quantum well structure and compositions thereof can be adjusted such that the semiconductor layers can emit light having a desired peak wavelength.

The p-type nitride semiconductor layer 135 can be grown on the active layer 133 and include a nitride semiconductor such as (Al, Ga, In)N and a p-type dopant.

The p-type semiconductor layer 135 can be grown by introducing a group III element source, a group V element source, and a p-type dopant precursor into the chamber at a first temperature. Here, the first temperature can range from about 900° C. to about 1100° C.; TMGa can be used as the group III element source; NH₃ can be used as the group V element source; Cp₂Mg can be used as a p-type dopant source; and N₂, H₂, or a gas in which N₂ and H₂ are mixed in a predetermined ratio can be used as a carrier gas. However, it should be understood that the present disclosure is not limited thereto and other implementations are also possible.

Then, when growth of the p-type nitride semiconductor layer 135 is completed, the interior of the chamber can be cooled to finish growth of the p-type nitride semiconductor layer 135. Here, cooling the interior of the chamber can include cooling from the first temperature to a second temperature, and introduction of the p-type dopant into the chamber can be maintained during cooling the interior of the chamber. The second temperature can be higher than or equal to a temperature at which bonds of hydrogen to the p-type dopant are dissociated, and can be, for example, a temperature of 400° C. or higher. In other words, after completion of growth of the p-type nitride semiconductor layer 135, the interior of the chamber is cooled while maintaining introduction of the p-type dopant, whereby out-diffusion of the p-type dopant from the p-type nitride semiconductor layer 135 can be prevented. Further, during the cooling process, a diffusion barrier layer 140 can be formed on an upper surface of the p-type nitride semiconductor layer 135.

Hereinafter, a method of growing a p-type nitride semiconductor layer 135 and a diffusion barrier layer 140 will be described in detail with reference to FIG. 3 to FIG. 5. According to this embodiment, Mg is used as the p-type dopant, and N₂ gas is used as the carrier gas. However, it should be understood that the present disclosure is not limited thereto, any element other than Mg can be used as the p-type dopant if capable of imparting p-type conductivity to nitride semiconductor layers, and any noble gas other than N₂ can be used as the carrier gas.

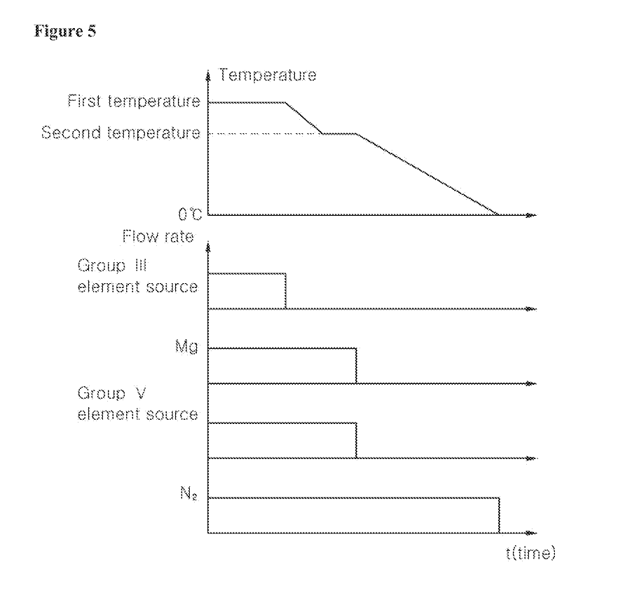

FIG. 5 illustrates a method of growing a p-type nitride semiconductor layer and a diffusion barrier layer. Referring to FIG. 5, after internal temperature of the chamber is set to the first temperature, a group III element source, a group V element source, Mg, and N₂ gas are introduced into the chamber to grow the p-type nitride semiconductor layer 135. Then, introduction of the group III element source into the chamber is stopped, followed by cooling the interior of the chamber to the second temperature while maintaining introduction of Mg into the chamber for a predetermined period of time. Here, after N₂ is introduced alone as the carrier gas to dissociate bonds of Mg and hydrogen, and the interior of the chamber is cooled further from the second temperature. In some implementations, the interior of the chamber can be maintained at the second temperature for a predetermined period of time. In addition, introduction of the group V element source can be maintained throughout the cooling process at least from the first temperature to the second temperature. Thus, diffusion of Mg from the p-type nitride semiconductor layer 135 into the chamber can be prevented.

Introduction flow rate of the Mg source and the carrier gas when forming the diffusion barrier layer can be higher than or equal to introduction flow rate of the Mg and the carrier gas when growing the p-type nitride semiconductor layer, and the introduction flow rate can start to be decreased at a point when cooling from the first temperature to the second temperature is initiated, or can be decreased during maintaining the interior of the chamber at the second temperature after completion of cooling.

Accordingly, as shown in FIG. 3, Mg and the group V element source within the chamber are deposited on the p-type nitride semiconductor layer 135 to form the diffusion barrier layer 140. Thus, the diffusion barrier layer 140 can include at least one of Mg or MgₓN_{y} according to whether the group V element source is introduced and introduction flow rate of the group V element source. The diffusion barrier layer 140 can be grown while cooling the interior of the chamber from the first temperature to the second temperature and/or while maintaining the interior of the chamber at the second temperature.

The diffusion barrier layer 140 is grown on the p-type nitride semiconductor layer 35 and thus can more effectively prevent diffusion of Mg from the p-type nitride semiconductor layer 135 into the chamber. For example, as shown in FIG. 4, the diffusion barrier layer 140 including Mg and/or MgₓN_{y} is grown on a surface of the p-type nitride semiconductor layer 135, whereby Mg contained in the p-type nitride semiconductor layer 135 can be effectively prevented from diffusing into the chamber 210.

The diffusion barrier layer 140 can have a thickness of about 0.3 nm to about 5 nm such that formation of a p-type electrode on the diffusion barrier layer 140 does not cause increase in contact resistance. In addition, the diffusion barrier layer (140) can include Mg, which is a conductive metal, and/or MgₓN_{y}, which is a conductive nitride, to be in ohmic contact with the p-type electrode. Thus, it is possible to prevent increase in forward voltage of a light emitting device fabricated by the method of growing a p-type nitride semiconductor layer 135 according to the embodiments of the present disclosure.

Although, in this embodiment, the method has been described by way of example wherein the p-type dopant is Mg, it should be understood the present disclosure is not limited thereto and includes a case in which other p-type dopants are used.

Further, after maintaining the interior of the chamber at the second temperature for a predetermined period of time, the interior of the chamber can be cooled to room temperature to complete fabrication of the p-type nitride semiconductor layer 135.

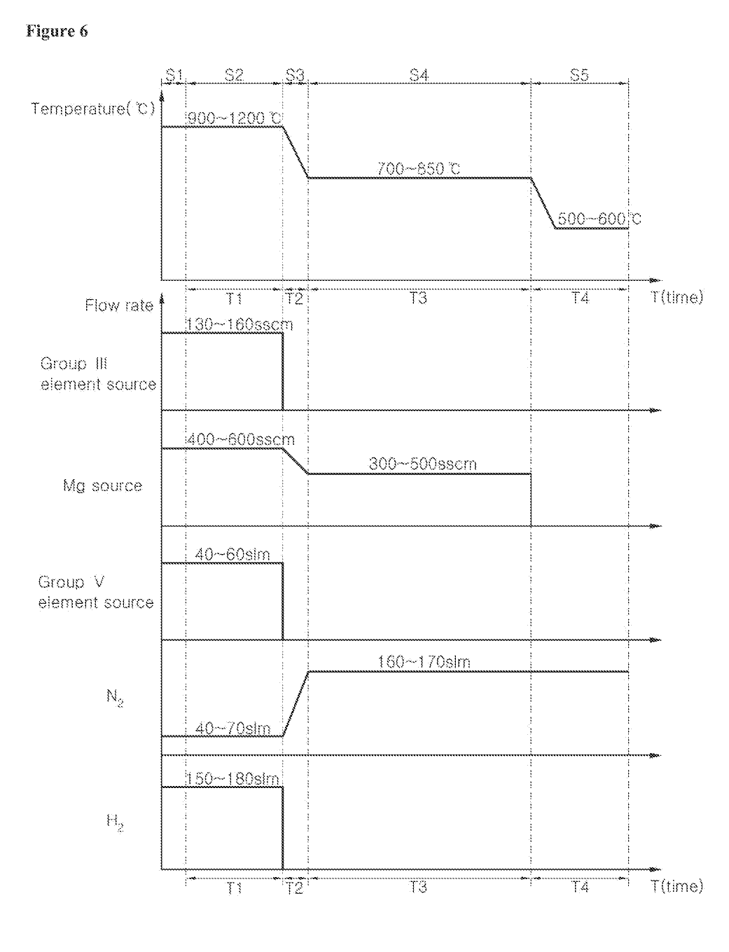

Hereinafter, methods of growing a p-type nitride semiconductor layer 135 according to embodiments of the present disclosure will be described more in detail with reference to FIG. 6 to FIG. 11.

FIG. 6 illustrates an exemplary method of growing a p-type nitride semiconductor layer 135 according to some embodiments of the present disclosure.

Referring to FIG. 6, growing the p-type nitride semiconductor layer 135 can include growing the p-type nitride semiconductor layer 135 during the first to fifth stages (S1 to S5). Here, the first to fifth stages (S1 to S5) can be performed for the first to fifth periods of time (T1 to T5), respectively. Internal pressure of the chamber during the first to fifth stages (S1 to S5) can range from 200 Torr to 400 Torr.

In the first stage (S1), the group III element source, the Mg source, the group V element source, and an atmosphere gas can be introduced into the growth chamber to grow the P-nitride semiconductor layer at the first temperature for T1. Here, in some implementations, the group III element source can include TMGa or TEGa, the Mg source can include Cp₂Mg, the group V element source can include NH₃, and the atmosphere gas can include H₂ and N₂.

For example, in the first stage (S1), about 130 sccm to about 160 sccm of TEGa, about 200 sccm to about 300 sccm of Cp₂Mg, about 40 slm to 60 slm of NH₃, about 40 slm to 70 slm of N₂, and about 150 slm to about 180 slm of H₂ can be introduced into the growth chamber for T1 while maintaining the interior of the chamber at about 900° C. to about 1200° C. to grow the P-nitride semiconductor layer. Accordingly, the P-nitride semiconductor layer can be grown into a P-GaN layer. In some implementations, when TMGa is used as the group III element source, TMGa can be introduced into the growth chamber at a flow rate of about 30 sccm to about 50 sccm. T1 can be adjusted according to a desired thickness of the P-GaN layer.

Then, in the second stage (S2), the sources and the atmosphere gas are introduced into the growth chamber in succession to the first stage (S1) while maintaining the growth temperature at substantially the same level as in the first stage, with only flow rate of the Mg source increased to grow a P⁺-nitride semiconductor layer. In other words, in the second stage (S2), by increasing flow rate of the Mg source while maintaining flow rates of the group III element source, the group V element source, and the atmosphere gas at the same level as in the first stage (S1), it is possible to grow the P⁺-nitride semiconductor layer having a higher doping concentration than the P-nitride semiconductor layer. Thus, the p-type nitride semiconductor layer 135 including the P-nitride semiconductor layer and the P⁺-nitride semiconductor layer can be grown. Growth of the P⁺-nitride semiconductor layer on the P-nitride semiconductor layer can reduce contact resistance between the p-type electrode and the p-type nitride semiconductor layer 135.

For example, in the second stage (S2), about 130 sccm to about 160 sccm of TEGa, about 400 sccm to about 600 sccm of Cp₂Mg, about 40 slm to about 60 slm of NH₃, about 40 slm to about 70 slm of N₂, and about 150 slm to about 180 slm of H₂ are introduced into the growth chamber for 3 minutes while maintaining the interior of the chamber at about 900° C. to about 1200° C. to grow the P⁺-nitride semiconductor layer. Accordingly, the P⁺-nitride semiconductor layer can be grown into a P⁺-GaN layer. On the other hand, when TMGa is used as the group III element source, TMGa can be introduced into the growth chamber at a flow rate of about 30 sccm to about 50 sccm.

Further, in the second stage (S2) wherein the P⁺-nitride semiconductor layer is grown, an In source such as TMIn or TEIn can be further introduced into the growth chamber. For example, TMIn can be further introduced into the growth chamber at a flow rate of about 400 sccm to about 500 sccm. Accordingly, the P⁺-nitride semiconductor layer can be grown into a P⁻-InGaN layer.

Next, in the third stage (S3), supply of the group III element source and the group V element source can be stopped; composition of the atmosphere gas can be changed; growth temperature can be decreased; and flow rate of the Mg source can be reduced. The flow rate of the Mg source can be decreased by about 10% to about 30% as compared with that of the Mg source in the second stage (S2), and the third stage (S3) can last for T3. Accordingly, growth of the P⁺-nitride semiconductor layer can be stopped.

For example, in the third stage (S3), the interior of the chamber is cooled to about 700° C. to about 850° C. for about 45 seconds. Here, before the starting point of the third stage (S3), supply of the group III element source, the group V element source, and H₂ is stopped. In addition, in the third stage (S3), flow rate of the Mg source is reduced to about 300 sccm to about 500 sccm, and flow rate of N₂ is increased to from about 160 slm to about 170 slm. Accordingly, growth of the P⁺-GaN layer can be stopped.

Next, in the fourth stage (S4), the Mg source and N₂ are introduced into the growth chamber for at least some time, while maintaining the chamber at the temperature having been dropped in the third stage (S3) for T4. Introduction of the Mg source into the growth chamber for at least some time can prevent out-diffusion of Mg from the P⁺-nitride semiconductor layer. Further, a diffusion barrier layer 140 containing Mg and/or MgₓN_{y} can be grown on the P⁺-nitride semiconductor layer. In other words, the diffusion barrier layer 140 can be grown on the p-type nitride semiconductor layer 135 by this in-situ heat treatment.

For example, in the fourth stage (S4), the inside of the growth chamber is maintained at about 700° C. to about 850° C. In addition, in the fourth stage (S4), flow rate of the Mg source is maintained at about 300 sccm to about 500 sccm, and flow rate of N₂ is maintained at about 160 slm to about 170 slm. Accordingly, the diffusion barrier layer 140 containing Mg and/or MgₓN_{y} can be grown. Here, the Mg source can be continuously introduced during the fourth stage (S4). However, it should be understood that the present disclosure is not limited thereto, and, alternatively, the Mg source can be introduced only for some time. Further, flow rate of the Mg source is not limited thereto, and can be less than or equal to flow rate of the Mg source introduced in the first stage (S1).

Next, in the fifth stage (S5), after introduction of the Mg source is stopped, the interior of the chamber is cooled to 500° C. to 600° C. under an N₂ atmosphere and maintained at that temperature for T5 (for example, about 5 minutes).

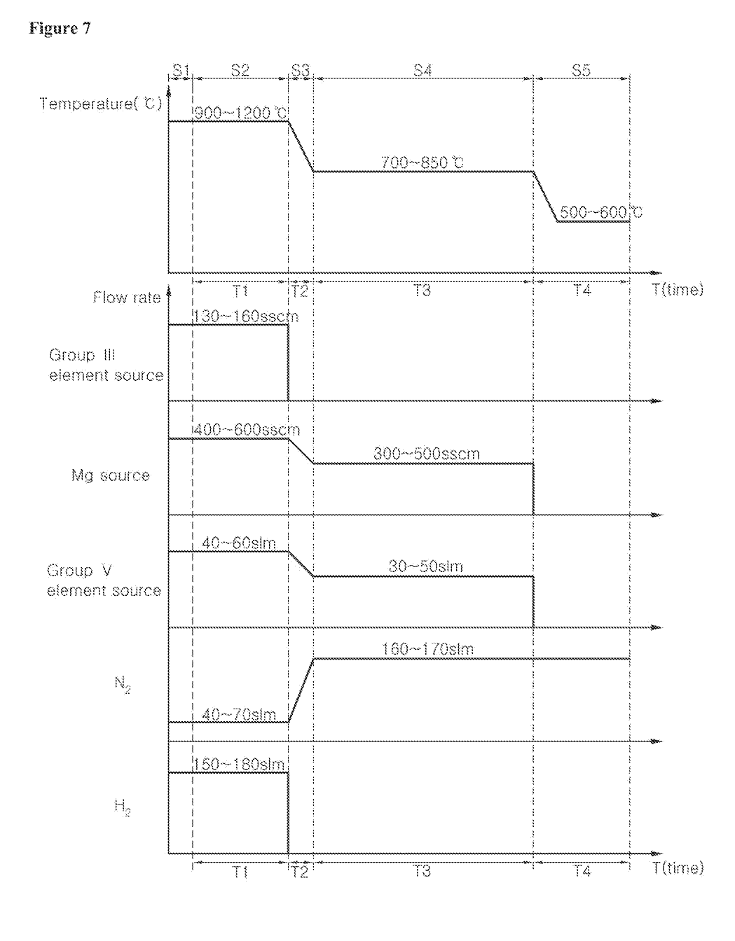

FIG. 7 illustrates an exemplary method of growing a p-type nitride semiconductor layer 135 and a diffusion barrier layer 140 according to some embodiments of the present disclosure.

Although substantially similar to the embodiment in FIG. 6, the embodiment in FIG. 7 differs from the embodiment in FIG. 6 in that supply of the group-V element source to the growth chamber is not stopped after the second stage (S2) but continued throughout the third and fourth stages (S3 and S4). Hereafter, only the different part will be described and descriptions of the same features will be omitted.

Referring to FIG. 7, in the second stage (S2), the group-V element source is introduced into the growth chamber at a first flow rate; in the third stage (S3), flow rate of the group-V element source is decreased to a second flow rate lower than the first flow rate; and, in the third stage (S4), the group-V element source is introduced into the growth chamber at the second flow rate. Here, the second flow rate can be about 10% to 30% lower than the first flow rate.

For example, NH₃ can be used as the group-V element source; in the second stage (S2), NH₃ is introduced into the growth chamber at a flow rate of about 40 slm to about 60 slm; in the third stage (S3), flow rate of NH₃ is decreased to about 30 slm to about 50 slm; and, in the fourth stage (S4), flow rate of NH₃ is maintained at about 30 slm to about 50 slm. Accordingly, a diffusion barrier layer 140 containing MgₓN_{y} can be grown, and the diffusion barrier layer can have increased percentage of nitride magnesium as compared with that of the embodiment in FIG. 5.

The diffusion barrier layer 140 containing MgₓN_{y} can prevent out-diffusion of Mg, and MgₓN_{y} can form a tunneling layer, thereby reducing contact resistance of the diffusion barrier layer 140.

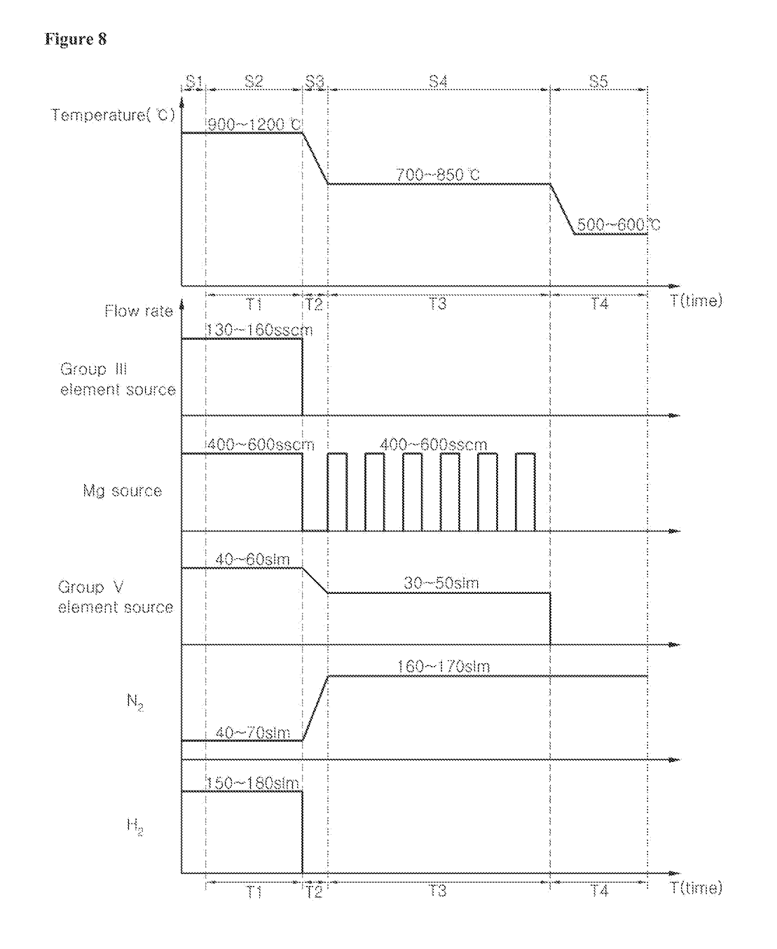

FIG. 8 illustrates an exemplary method of growing a p-type nitride semiconductor layer 135 and a diffusion barrier layer 140 according to some embodiments of the present disclosure.

Although substantially similar to the embodiment in FIG. 7, the embodiment in FIG. 8 differs from the embodiment in FIG. 7 in that, in the fourth stage (S4), the Mg source is supplied in a pulse mode. Hereafter, only the different part will be described and descriptions of the same features will be omitted.

Referring to FIG. 8, in the fourth stage (S4), the Mg source can be introduced into the growth chamber in a multi-pulse mode. Specifically, for example, introduction of Cp₂Mg into the growth chamber at a flow rate of about 400 sccm to about 600 sccm for a predetermined period of time (for example, about 1 minute) and supply suspension of Cp₂Mg for a predetermined period of time (for example, about 1 minute) can be repeated in an alternating manner. Thus, introduction flow rate of Cp₂Mg can appear in the form of a rectangular wave, as shown in FIG. 8. Here, the number of cycles in which introduction and supply suspension of Cp₂Mg are repeated can range from 3 to 7.

Even when introduction of Cp₂Mg is suspended in the fourth stage (S4), an MgₓN_{y} layer having a relatively low Mg concentration can be grown by the Mg source remaining in the growth chamber. Accordingly, during introduction of Cp₂Mg, an Mg-rich MgₓN_{y} layer having a relatively high Mg concentration can be grown, whereas, during supply suspension of Cp₂Mg, an Mg-poor MgₓN_{y} layer having a relatively low Mg concentration can be grown. Thus, the diffusion barrier layer 140 can include a structure in which the Mg-rich MgₓN_{y} layer having a relatively high Mg concentration and the Mg-poor MgₓN_{y} layer having a relatively low Mg concentration are repeatedly stacked in an alternate manner. Such a multilayer-structured diffusion barrier layer 140 can further effectively prevent out-diffusion of Mg.

In addition, by repeatedly stacking the Mg-rich MgₓN_{y} layer and the Mg-poor MgₓN_{y} layer, it is possible to prevent the MgₓN_{y} layer from completely covering the p-type semiconductor layer 135 and causing deterioration in ohmic contact properties due to tunneling, thereby avoiding increase in contact resistance caused by the diffusion barrier layer 140.

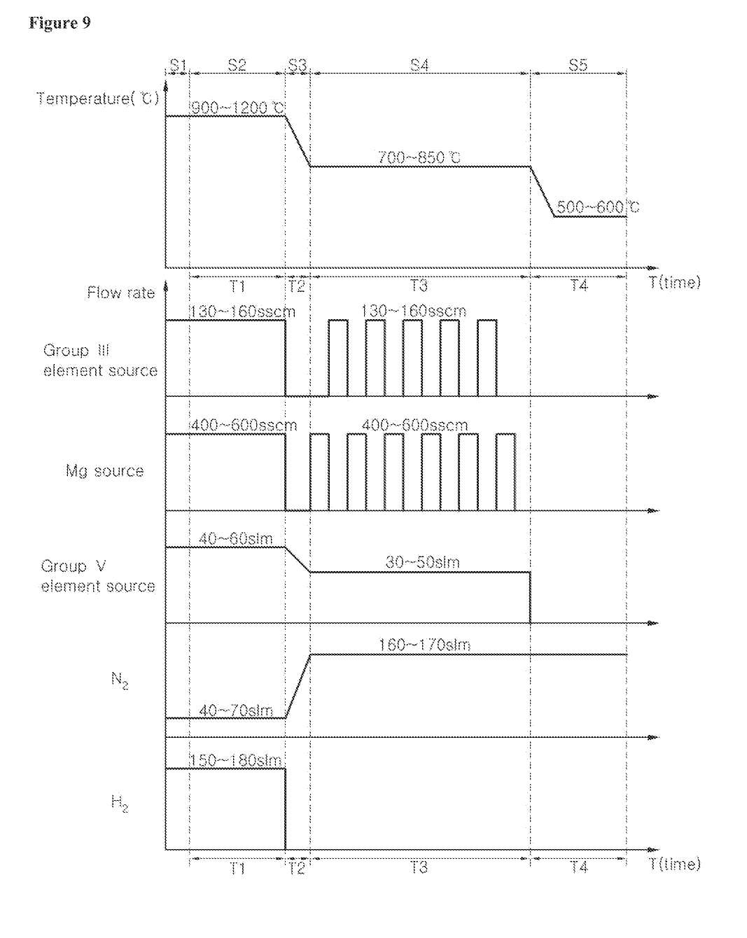

FIG. 9 illustrates an exemplary method of growing a p-type nitride semiconductor layer 135 and a diffusion barrier layer 140 according to some embodiments of the present disclosure.

Although substantially similar to the embodiment in FIG. 8, the embodiment in FIG. 9 differs from the embodiment in FIG. 8 in that, in the fourth stage (S4), the group III element source is further introduced into the growth chamber during supply suspension of the Mg source. Hereinafter, only the different part will be described and descriptions of the same features will be omitted.

Referring to FIG. 9, in the fourth stage (S4), the Mg source and the group III element source can be introduced into the growth chamber in a multi-pulse mode. In addition, the Mg source and the group III element source can be alternately introduced into the growth chamber.

For example, Cp₂Mg and TEGa can be introduced into the growth chamber as the Mg source and the group-III element source, respectively. Introduction of Cp₂Mg into the growth chamber at a flow rate of about 400 sccm to about 600 sccm for a predetermined period of time (for example, about 1 minute) and supply suspension of Cp₂Mg for a predetermined period of time (for example, about 1 minute) can be repeated. Similarly, introduction of TEGa into the growth chamber at a flow rate of about 130 sccm to about 160 sccm for a predetermined period of time (for example, about 1 minute) and supply suspension of TEGa for a predetermined period of time (for example, about 1 minute) can be repeated. Thus, introduction flow rates of Cp₂Mg and TEGa can appear in the form of a rectangular wave, as shown in FIG. 9. Here, introduction of TEGa can be suspended during introduction of Cp₂Mg, and vice versa.

In this embodiment, although the method has been described by way of example wherein the growth chamber is cooled subsequent to deceasing flow rates of Cp₂Mg, which is a p-type dopant source, and NH₃, which is a group V source gas, the present disclosure is not limited thereto and other implementations are also possible. Alternatively, flow rates of Cp₂Mg and NH₃ can be the same as those when growing the p-type semiconductor layer, or can be decreased by 30% or more.

Accordingly, an MgₓN_{y} layer can be grown during introduction of Cp₂Mg, and a GaN layer can be grown during introduction of TEGa. Thus, the diffusion barrier layer 140 can include a structure in which the MgₓN_{y} layer and the GaN layer are repeatedly stacked. Here, each of the MgₓN_{y} layer and the GaN layer can be composed of or include a monolayer. Further, the GaN layer can further include Mg remaining in the growth chamber to be doped into a p-type.

Since the diffusion barrier layer 140 includes the aforementioned repeated stack structure, out-diffusion of Mg can further effectively be prevented. In addition, by repeatedly stacking the MgₓN_{y} layer and the GaN layer, it is possible to prevent the MgₓN_{y} layer from completely covering the p-type semiconductor layer 135 and thus causing deterioration in ohmic contact properties (saturation of the MgₓN_{y} layer) due to tunneling, thereby avoiding increase in contact resistance caused by the diffusion barrier layer 140. Further, by repeatedly stacking the MgₓN_{y} layer and the GaN layer, it is possible to increase tunneling effects, thereby reducing contact resistance between the p-type nitride semiconductor layer and the p-type electrode.

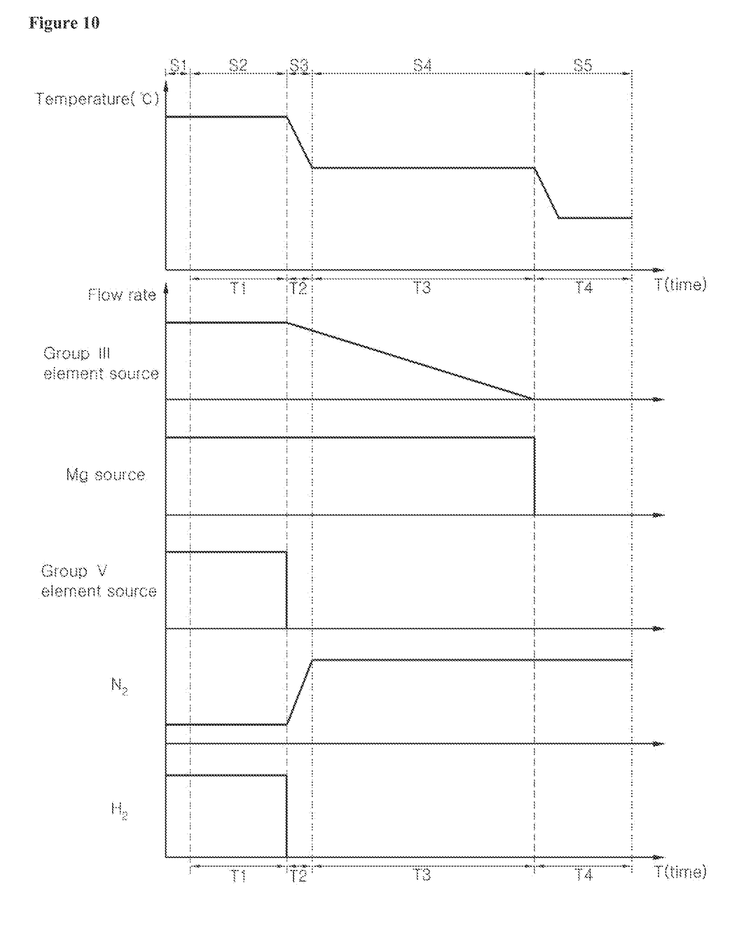

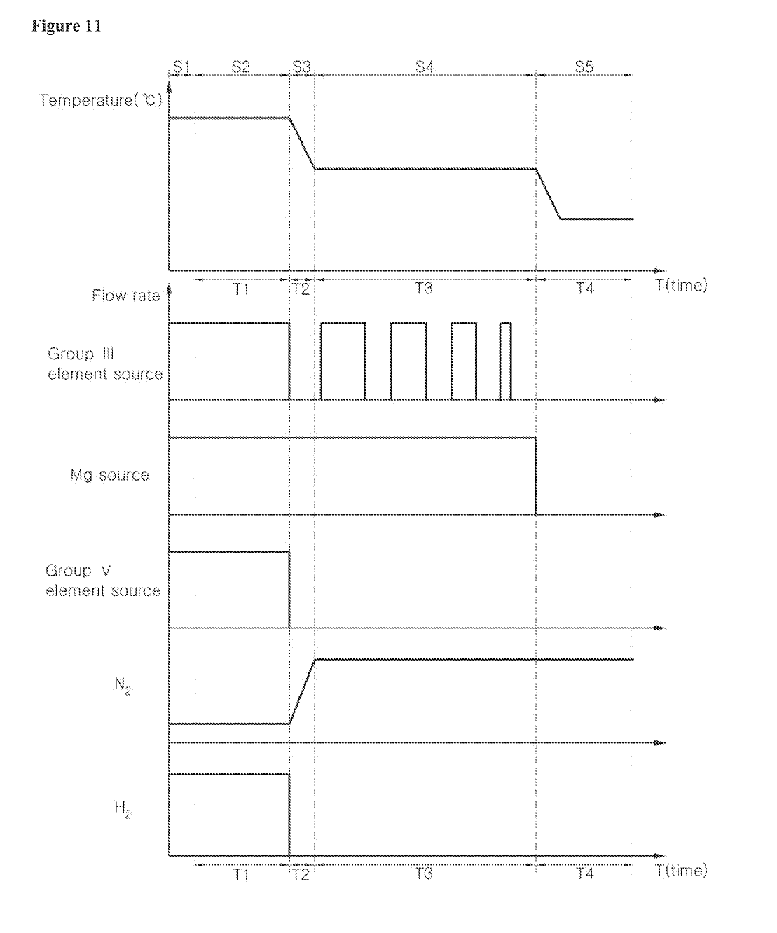

FIG. 10 illustrates an exemplary method of growing a p-type nitride semiconductor layer 135 and a diffusion barrier layer 140 according to some embodiments of the present disclosure.

Although substantially similar to the embodiment in FIG. 6, the embodiment in FIG. 10 differs from the embodiment in FIG. 6 in that flow rate of the Mg source is not decreased in the third stage (S3) and supply of the group III element source is not stopped after the second stage (S2) but monotonically or gradually decreased with time. Hereinafter, only the different part will be described and descriptions of the same features will be omitted.

Referring to FIG. 10, the Mg source is introduced into the growth chamber at a substantially constant flow rate during the second to fourth stages (S2 to S4). For example, about 400 sccm to about 600 sccm of Cp₂Mg can be introduced into the growth chamber for a predetermined period of time (for example, for T2 to T3). For example, according to this embodiment, during the third to fourth stages (S3 to S4), the group-III element source can be introduced into the growth chamber for at least some time. Further, during the third to fourth stages (S3 to S4), flow rate of the group III element source introduced into the growth chamber can be monotonically or gradually decreased. For example, as shown in FIG. 10, TEGa (and/or TMGa) can be introduced as the group III element source into the growth chamber for T2 and T3 in the third and fourth stages (S3 and S4), wherein introduction flow rate of the group III element source can be decreased at a constant reduction rate with time. However, flow rate of the group III element source is not limited to a case of monotonic or gradual decrease. Alternatively, introduction flow rate of the group III element source can be decreased at a varying reduction rate for at least some time.

As such, decrease in flow rate of the group III element source while introducing the Mg source into the growth chamber at a substantially constant flow rate can cause formation of MgₓN_{y} in the diffusion barrier layer 140. Accordingly, it is possible to reduce probability of Mg out-diffusion and lower contact resistance of the diffusion barrier layer 140.

FIG. 11 illustrates an exemplary method of growing a p-type nitride semiconductor layer 135 and a diffusion barrier layer 140 according to some embodiments of the present disclosure.

Although substantially similar to the embodiment in FIG. 10, the embodiment in FIG. 11 differs from the embodiment in FIG. 10 in that the group III element source is introduced into the growth chamber in a multi-pulse mode. Hereinafter, only the different part will now be described and description of the same features will be omitted.

Referring to FIG. 11, the Mg source is introduced into the growth chamber at a substantially constant flow rate during the second to fourth stages (S2 to S4). For example, about 400 sccm to about 600 sccm of Cp₂Mg can be introduced into the growth chamber for a predetermined period of time (for example, for T2 to T3). According to this embodiment, during the third to fourth stages (S3 to S4), the group-III element source can be introduced into the growth chamber for at least some time. For example, during the third to fourth stages (S3 to S4), the group III element source can be supplied in a multi-pulse mode. Further, a subsequent pulse can have a shorter duration than a preceding pulse. For example, as shown in FIG. 11, TEGa (and/or TMGa) can be introduced as the group III element source into the growth chamber in a multi-pulse mode, wherein a subsequent pulse can have a shorter duration than a preceding pulse. Thus, in the multi-pulse mode, duration of each pulse can be decreased with time. Feeding frequency of the pulse is not restricted. In addition, flow rate of the group III element source can be constant or vary for each pulse.

As such, the group III element source is introduced into the growth chamber in a multi-pulse mode, wherein duration of each pulse can be reduced while introducing the Mg source into the growth chamber at a substantially constant flow rate. The sources are supplied to the growth chamber as describe above, thereby inducing formation of MgₓN_{y} in the diffusion barrier layer 140. For example, duration of the pulse of supplying the group III element source is decreased, whereby MgₓN_{y} can be grown in an upper region of the diffusion barrier layer 140 at a relatively high density. Accordingly, it is possible to reduce probability of Mg out-diffusion and lower contact resistance of the diffusion barrier layer 140.

Referring again to FIG. 3, a light emitting device including a structure as shown in FIG. 3 can be provided using the method of fabricating a p-type nitride semiconductor layer 135.

The light emitting device can include an n-type nitride semiconductor layer 131, an active layer 133, a p-type nitride semiconductor layer 135, and a diffusion barrier layer 140. In addition, the light emitting device can further include a p-type electrode (not shown) which is disposed on the diffusion barrier layer 140 and is in ohmic contact with the diffusion barrier layer 140.

The light emitting device is not restricted in terms of structure or configuration thereof. For example, the structure of the p-type nitride semiconductor 135 and the diffusion barrier layer 140 according to the present disclosure can be applied to various light emitting devices such as vertical type, horizontal type, or flip chip type light emitting devices. The growth substrate 110 can be omitted, and known techniques not described herein can be used, as needed.

In the method of growing a p-type nitride semiconductor layer and a light emitting device fabricated using the same according to the present disclosure, it is possible to prevent increase in contact resistance between a p-type electrode and a p-type nitride semiconductor layer. Accordingly, it is possible to prevent increase in forward voltage of the light emitting device while avoiding deterioration in luminous efficiency due to increase in contact resistance.

Moreover, the method of growing a p-type nitride semiconductor layer can achieve considerable effects simply by maintaining introduction of a p-type dopant without a need for a separate source gas or an additional process in the growth process. Thus, it is possible to provide a light emitting device having excellent forward voltage properties without substantial modification of a typical process of fabricating a light emitting device.

It should be understood that the present disclosure is not limited to the embodiments and features described above, and various modifications and changes can be made without departing from the scope of the present disclosure, as set forth in the following claims.

What is claimed is:

1. A method of fabricating a light emitting device, comprising:
growing an n-type nitride semiconductor layer over a growth substrate;
growing an active layer over the n-type nitride semiconductor layer;
growing a p-type nitride semiconductor layer over the active layer by introducing a group III element source, a group V element source, and a p-type dopant into a chamber at a first temperature; and
cooling an interior of the chamber from the first temperature to a second temperature,
wherein the p-type dopant is introduced into the chamber for at least some part of the cooling of the interior of the chamber from the first temperature to the second temperature.

2. The method of claim 1, wherein the cooling of the interior of the chamber from the first temperature to the second temperature includes growing a diffusion barrier layer including the p-type dopant over the p-type nitride semiconductor layer.

3. The method of claim 2, wherein the p-type dopant includes Mg and the diffusion barrier layer includes at least one of Mg or MgₓN_{y}.

4. The method of claim 2, including:
stopping the introducing of the group III element source into the chamber and maintaining the introducing of the group V element source during cooling of the interior of the chamber from the first temperature to the second temperature.

5. The method of claim 2, further including:
maintaining the interior of the chamber at the second temperature for a predetermined period of time after cooling the interior of the chamber to the second temperature,
wherein the p-type dopant is introduced into the chamber for at least some part of the maintaining, and
wherein growing the diffusion barrier layer is continued during the maintaining of the interior of the chamber at the second temperature.

6. The method of claim 5, wherein the introducing of the group V element source is maintained during the cooling process and the maintaining process, and
a flow rate of the group V element source introduced during the growth of the p-type nitride semiconductor layer is higher than or equal to a flow rate of the group V element source introduced during the growth of the diffusion barrier layer.

7. The method of claim 6, wherein a flow rate of the p-type dopant introduced during the growth of the p-type nitride semiconductor layer is higher than or equal to a flow rate of the p-type dopant introduced during the growth of the diffusion barrier layer.

8. The method of claim 6, wherein the p-type dopant is introduced into the chamber in a multi-pulse mode during the growing of the diffusion barrier layer, and
the diffusion barrier layer includes a structure in which an Mg-rich MgₓN_{y} layer and an Mg-poor MgₓN_{y} layer are stacked more than once.

9. The method of claim 6, wherein the group III element source and the p-type dopant are introduced into the chamber in a multi-pulse mode during the growing of the diffusion barrier layer, and
the diffusion barrier layer includes a structure in which an MgₓN_{y} layer and a GaN layer are stacked more than once.

10. A light emitting device comprising:
an n-type nitride semiconductor layer;
an active layer disposed over the n-type nitride semiconductor layer;
a p-type nitride semiconductor layer disposed over the active layer; and
a diffusion barrier layer disposed over the p-type nitride semiconductor layer.

11. The light emitting device of claim 10, wherein the diffusion barrier layer includes a p-type dopant.

12. The light emitting device of claim 11, wherein the p-type dopant includes Mg and the diffusion barrier layer includes at least one of Mg or MgₓN_{y}.

13. The light emitting device of claim 12, wherein the diffusion barrier layer includes a structure in which an Mg-rich MgₓN_{y} layer and an Mg-poor MgₓN_{y} layer are repeatedly stacked.

14. The light emitting device of claim 12, wherein the diffusion barrier layer includes a structure in which an MgₓN_{y} and a GaN layer are repeatedly stacked.

15. The light emitting device of claim 12, the diffusion barrier layer has a thickness from 0.3 nm to 5 nm.

16. The light emitting device of claim 14, wherein the GaN layer includes Mg.

17. The light emitting device of claim 10, further including:
a p-type electrode disposed over the diffusion barrier layer,
wherein the p-type electrode forms ohmic contact with the diffusion barrier layer.

18. The method of claim 2, further including: during the cooling of the interior of the chamber from the first temperature to the second temperature, gradually decreasing a flow rate of the group III element source for at least some part of a period of time for which the p-type dopant is introduced into the chamber.

19. The method of claim 2, wherein the group III element source is introduced into the chamber in a multi-pulse mode for at least some part of a period of time for which the p-type dopant is introduced into the chamber during the maintaining the interior of the chamber at the second temperature, and
in the multi-pulse mode, a subsequent pulse has a shorter duration than a preceding pulse.

20. The method of claim 2, during the growing of the p-type nitride semiconductor layer, increasing a flow rate of the p-type dopant such that the p-type nitride semiconductor layer includes a P-nitride semiconductor layer and a P⁺-nitride semiconductor layer.
